(19) United States
(12) Patent Application Publication
(10) Pub. No.: US 2006/0059288 A1
(43) Pub. Date: Mar. 16, 2006

(54) Reduced speed I/O from rear transition module

(76) Inventors: Sarah M. Wolfe, Scottsdale, AZ (US); Jeffrey M. Harris, Chandler, AZ (US); Malcolm J. Rush, Phoenix, AZ (US)

Correspondence Address: MOTOROLA, INC., LAW DEPARTMENT, 1303 E. ALGONQUIN ROAD, SCHAUMBURG, IL, 60196, US

(21) Appl. No.: 10/917,092

(22) Filed: Aug. 12, 2004

(51) Int. Cl. H05K 7/10; G06F 13/36; G06F 13/00

(52) U.S. Cl. 710/301; 710/316; 710/306

(57) ABSTRACT

A VXS multi-service platform system (200) includes a VXS computer chassis (103), a monolithic backplane (102) in the VXS computer chassis, a VMEbus network (108) on the monolithic backplane, and a switched fabric (110) operating coincident with the VMEbus network on the monolithic backplane. A front module (105) is coupled to a front portion (104) of the monolithic backplane. A rear transition module (118, 120) is coupled to a rear portion (106) of the monolithic backplane, where the rear transition module is substantially coplanar with the front module. A switched fabric link (260, 360) extends from the front module through the monolithic backplane to the rear transition module, where the switched fabric link operates using a switched fabric protocol (270, 370). An RTM bridging unit (280, 380) is included on the rear transition module, where the switched fabric link terminates at the RTM bridging unit, where the RTM bridging unit bridges the switched fabric protocol to an external link (262, 362) operating an external I/O protocol (282, 382), where the external I/O protocol transfers data at least an order of magnitude slower than the switched fabric protocol, and where the external link extends outside of the VXS computer chassis from the rear transition module.

### BACKGROUND OF THE INVENTION

In current embedded computer platforms, such as VERSAmodule Eurocard (VMEbus) systems, the shared multi-drop bus can only be used to support one simultaneous communication between modules in the network. However, some applications have requirements for simultaneous high bandwidth transfers between modules in the VMEbus system that cannot be handled by the shared multi-drop architecture of VMEbus. It is desirable to configure current VMEbus systems to accommodate high-speed data transfers while maintaining the existing VMEbus network architecture. Prior art VME cards have a limited number of pins in the backplane connectors. This limits the number of input and output (I/O) circuit paths that can be accommodated between a VME card and a rear transition module. Therefore, the number of I/O lines coupling a VME chassis to outside entities is limited by these circuit paths.

Accordingly, there is a significant need for an apparatus and method that overcomes the deficiencies of the prior art outlined above.

### BRIEF DESCRIPTION OF THE DRAWINGS

Referring to the drawing:

FIG. 1 depicts a VXS multi-service platform system according to one embodiment of the invention;

FIG. 2 depicts a VXS multi-service platform system according to an embodiment of the invention; and

FIG. 3 depicts a VXS multi-service platform system according to another embodiment of the invention.

It will be appreciated that for simplicity and clarity of illustration, elements shown in the drawing have not necessarily been drawn to scale. For example, the dimensions of some of the elements are exaggerated relative to each other. Further, where considered appropriate, reference numerals have been repeated among the Figures to indicate corresponding elements.

### DESCRIPTION OF THE PREFERRED EMBODIMENTS

In the following detailed description of exemplary embodiments of the invention, reference is made to the accompanying drawings, which illustrate specific exemplary embodiments in which the invention may be practiced. These embodiments are described in sufficient detail to enable those skilled in the art to practice the invention, but other embodiments may be utilized and logical, mechanical, electrical and other changes may be made without departing from the scope of the present invention. The following detailed description is, therefore, not to be taken in a limiting sense, and the scope of the present invention is defined only by the appended claims.

In the following description, numerous specific details are set forth to provide a thorough understanding of the invention. However, it is understood that the invention may be practiced without these specific details. In other instances, well-known circuits, structures and techniques have not been shown in detail in order not to obscure the invention.

For clarity of explanation, the embodiments of the present invention are presented, in part, as comprising individual functional blocks. The functions represented by these blocks may be provided through the use of either shared or dedicated hardware, including, but not limited to, hardware capable of executing software. The present invention is not limited to implementation by any particular set of elements, and the description herein is merely representational of one embodiment.

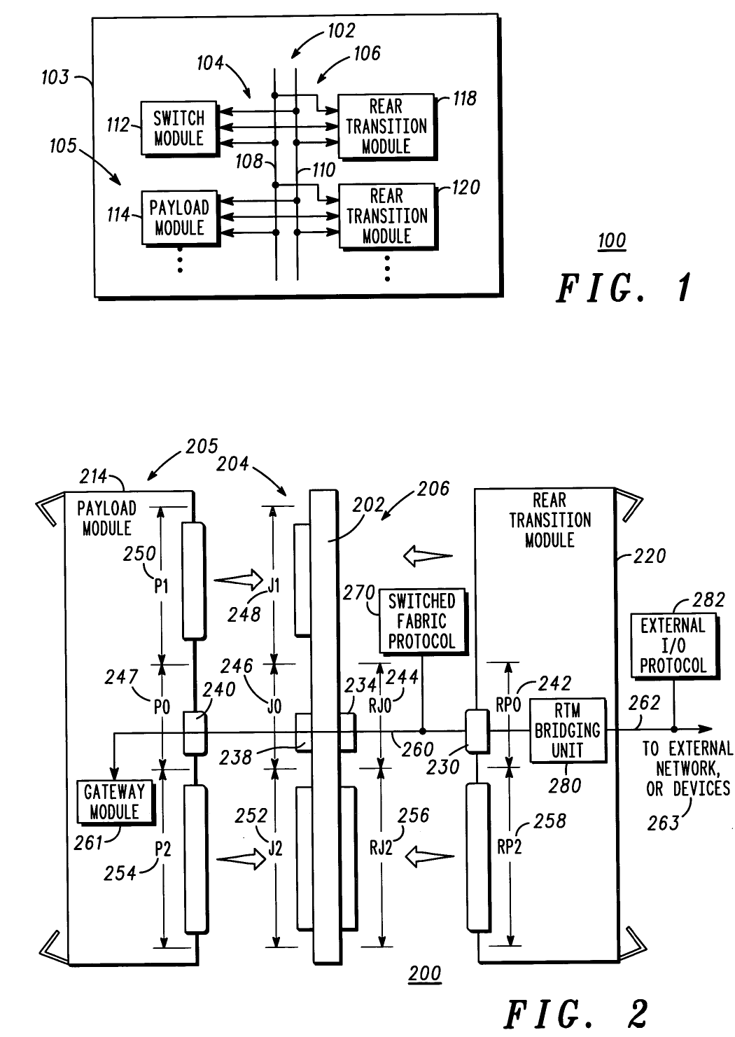

FIG. 1 depicts a VXS multi-service platform system 100 according to one embodiment of the invention. A VXS multi-service platform system 100 can include one or more computer chassis, with software and any number of slots for inserting a front module 105, which can be, for example and without limitation, a payload module 114, a switch module 112, and the like. Slots can also be present for inserting one or more rear transition modules 118, 120. Modules can add functionality to VXS multi-service platform system 100 through the addition of processors, memory, storage devices, device interfaces, network interfaces, and the like. In one embodiment a backplane connector is used for connecting modules placed in the slots. In an embodiment, VXS multi-service platform system 100 is an embedded, distributed processing computer system.

In an embodiment, VXS multi-service platform system 100 comprises an embedded-type computer system having a single chassis supporting a monolithic backplane 102 and further comprising individual slots. In this embodiment, monolithic backplane 102 includes a single backplane in a single VXS computer chassis 103. In an embodiment, slots on the front portion 104 of the monolithic backplane 102 are coupled for receiving switch module 112 and payload module 114 that plug into the monolithic backplane 102. In an embodiment, slots on the rear portion 106 of monolithic backplane 102 are coupled for receiving rear transition modules 118, 120 that also plug into the monolithic backplane 102. In an embodiment, front portion 104 and rear portion are on substantially opposite sides of monolithic backplane 102. In an embodiment, each payload module and rear transition module can have a standardized form factor including physical dimensions, electrical connections, and the like as specified in an industry standard specification, for example VERSAmodule Eurocard (VMEbus), VXS, and the like, as described further below.

As an example of an embodiment, VXS multi-service platform system 100 can include VXS computer chassis 103 and one or more modules conforming to the VERSAmodule Eurocard (VMEbus) switched serial standard backplane (VXS) as set forth in VITA 41 promulgated by VMEbus International Trade Association (VITA), P.O. Box 19658, Fountain Hills, Ariz., 85269. VXS multi-service platform system 100 includes a packet switched network, known as a switched fabric 110 and a VMEbus network 108, both located on monolithic backplane 102. In other words, a VXS multi-service platform system 100 includes switched fabric 110 coincident with VMEbus network 108 on monolithic backplane 102.

In an embodiment, VXS multi-service platform system 100 can be controlled by a platform controller (not shown for clarity), which can include a processor for processing algorithms stored in memory. Memory comprises control algorithms, and can include, but is not limited to, random access memory (RAM), read only memory (ROM), flash memory, electrically erasable programmable ROM (EEPROM), and the like. Memory can contain stored instructions, tables, data, and the like, to be utilized by a processor. Platform controller can be contained in one, or distributed among two or more payload modules with communication among the various modules of VXS multi-service platform system 100.

Switched fabric 110 allows all payload modules equipped to communicate with the switched fabric to be coupled to all other payload modules similarly equipped. Switched fabric 110 operating on monolithic backplane 102 can use a switch module 112 as a central switching hub with any number of payload modules 114 coupled to switch module 112. Although FIG. 1 depicts switched fabric 110 as a bus for diagrammatic ease, switched fabric 110 may in fact be a star topology, mesh topology, and the like as known in the art for communicatively coupling switched fabrics. Switched fabric 110 can be based on a point-to-point, switched input/output (I/O) fabric, whereby cascaded switch devices interconnect end node devices. In an embodiment, switched fabric 110 supports data transfer at multi-gigabyte rates, for example data transfer in excess of two gigabytes per second. Monolithic backplane 102 can be implemented by using one or more of a plurality of switched fabric protocols, for example and without limitation, InfiniBand™, Serial RapidIO™, FibreChannel™, Ethernet™, PCI Express™, Universal Serial Bus (USB), Serial AT Attachment (Serial ATA), Serial Attached Small Computer System Interface (Serial Attached SCSI), and the like. Monolithic backplane 102 is not limited to the use of these switched fabric protocols and the use of any switched fabric protocol is within the scope of the invention.

VMEbus network 108 is a parallel multi-drop bus network that is known in the art. VMEbus network 108 is defined in the ANSI/VITA 1-1994 and ANSI/VITA 1.1-1997 standards, promulgated by the VMEbus International Trade Association (VITA), P.O. Box 19658, Fountain Hills, Ariz., 85269 (where ANSI stands for American National Standards Institute). In an embodiment of the invention, VMEbus network 108 can include VMEbus based protocols such as Single Cycle Transfer protocol (SCT), Block Transfer protocol (BLT), Multiplexed Block Transfer protocol (MBLT), Two Edge VMEbus protocol (2 eVME) and Two Edge Source Synchronous Transfer protocol (2eSST). VMEbus network 108 is not limited to the use of these VMEbus based protocols and other VMEbus based protocols are within the scope of the invention.

In an embodiment of the invention, VMEbus network 108 and switched fabric 110 operate concurrently within VXS multi-service platform system 100. In one embodiment, switched fabric 110 operates in parallel with VMEbus network 108 in a VXS multi-service platform system 100.

In an embodiment, payload module 114 and rear transition modules 118, 120 can have a physical form factor including physical dimensions, electrical connections, and the like as set forth in the ANSI/VITA 1-1994 and ANSI/VITA 1.1-1997 standards.

In an embodiment, rear transition modules 118, 120 can be used to interface VXS computer chassis 103 to external networks, devices, and the like. Also, rear transition modules 118, 120 can be used to interface VXS multi-service platform system 100 with devices such as storage drives, memory, processors, and the like.

In an embodiment, each rear transition module can have a corresponding payload module or corresponding switch module. For example, rear transition module 120 has corresponding payload module 114. Also, rear transition module 118 has corresponding switch module 112. In an embodiment, within VXS computer chassis 103, rear transition module is substantially coplanar to its corresponding payload module or corresponding switch module. This can mean that rear transition module coupled to rear portion 106 of monolithic backplane 102 is substantially in the same plane as its corresponding payload module or corresponding switch module coupled to the front portion 104 of monolithic backplane 102.

In an embodiment, rear transition module 120 can be coupled directly to switched fabric 110 and/or VMEbus network 108. Also, rear transition module 120 can be coupled to corresponding payload module 114 through monolithic backplane 102. In the embodiment shown, rear transition module 120 is shown coupled to VMEbus network 108, switched fabric 110 and payload module 114. This is not limiting of the invention as rear transition module 120 can be coupled to any combination of VMEbus network 108, switched fabric 110 and payload module 114 and be within the scope of the invention.

In another embodiment, rear transition module 118 is coupled to corresponding switch module 112 through monolithic backplane 102. Rear transition module 118 can also be coupled to VMEbus network 108 and/or switched fabric 110. In the embodiment shown, rear transition module 118 is shown coupled to VMEbus network 108, switched fabric 110 and switch module 112. This is not limiting of the invention as rear transition module 118 can be coupled to any combination of VMEbus network 108, switched fabric 110 and switch module 112 and be within the scope of the invention.

FIG. 2 depicts a VXS multi-service platform system 200 according to an embodiment of the invention. In an embodiment of the invention, monolithic backplane 202 and front module 205 have a set of interlocking connectors designed to interlock with each other when front module 205 is placed in a slot of VXS multi-service platform system 200. In an embodiment, front module 205 can be payload module 214, which is coupled to interface with front portion 204 of monolithic backplane 202. Mechanical and electrical specifications for a portion of these interlocking connectors can be found in the ANSI/VITA 1-1994 and ANSI/VITA 1.1-1997 and the VITA 41 standards cited above for VMEbus systems. For example, these standards define P0 mechanical envelope 247, P1 mechanical envelope 250, and P2 mechanical envelope 254 on payload module 214. These standards further define corresponding J0 mechanical envelope 246, J1 mechanical envelope 248, and J2 mechanical envelope 252 on monolithic backplane 202. Connectors in the P0/J0, P1/J1 and P2/J2 mechanical envelopes can interlock when payload module 214 is placed in a slot of VXS multi-service platform system 200.

In an embodiment, payload module 214 has one portion of an interlocking connector in the P1 mechanical envelope 250 designed to interlock with its corresponding portion located in the J1 mechanical envelope 248 on monolithic backplane 202. Also, payload module 214 can have an interlocking connector in the P2 mechanical envelope 254 designed to interlock with its corresponding portion located in the J2 mechanical envelope 252 on monolithic backplane 202.

In an embodiment of the invention, connectors in the P1/J1 and P2/J2 mechanical envelopes are for coupling VMEbus network 108 to payload module 214, while the connector in P0/J0 mechanical envelope is for coupling switched fabric 110 to payload module 214. When payload module 214 is placed in a slot and coupled to monolithic backplane 202 via connectors in the P1/J1 and P2/J2 mechanical envelopes, the functionality of payload module 214 is added to VXS multi-service platform system 200 via VMEbus network 108. For example, processors, memory, storage devices, I/O elements, and the like, on payload module 214 are accessible by other payload modules in VXS multi-service platform system 200 and vice versa. When payload module 214 is placed in a slot and coupled to monolithic backplane 202 via a connector in the P0/J0 mechanical envelopes, the functionality of payload module 214 is added to VXS multi-service platform system 200 via switched fabric 110.

In this embodiment, payload module 214 can have payload module connector 240 in the P0 mechanical envelope 247 as defined in the VXS specification above. Monolithic backplane 202 can include payload connector 238 in the J0 mechanical envelope 246, where the payload module connector 240 and the payload connector 238 are designed to interface and interlock when payload module 214 is inserted into VXS multi-service platform system 200. In an embodiment, payload module connector 240 and payload connector 238 can be electrical, optical, radio frequency, biological, and the like, type connectors. In an embodiment, payload module connector 240 and payload connector 238 are designed for use in high-speed switched fabrics and are compatible with any of a plurality of switched fabric protocols 270 discussed above. Switched fabric 110 on monolithic backplane 202 can operate using any of switched fabric protocols 270.

In an example of an embodiment of the invention, payload module connector 240 in the P0 mechanical envelope 247 and payload connector 238 in the J0 mechanical envelope 246 can be a Tyco MultiGig RT connector manufactured by the AMP division of Tyco Electronics, Harrisburg, Pa. The invention is not limited to the use of the Tyco RT connector, and any connector capable of handling data using any of the plurality of switched fabric network standards is encompassed within the invention.

In the embodiment depicted in FIG. 2, VXS multi-service platform system 200 can include rear transition module 220 coupled to interface with rear portion 206 of monolithic backplane 202. In an embodiment, rear transition module 220 is substantially coplanar with corresponding payload module 214.

In an embodiment of the invention, monolithic backplane 202 and rear transition module 220 have a set of interlocking connectors designed to interlock with each other when rear transition module 220 is placed in a slot of VXS multi-service platform system 200. Rear transition module 220 is coupled to interface with rear portion 206 of monolithic backplane 202. Mechanical and electrical specifications for a portion of these interlocking connectors can be found in the ANSI/VITA 1-1994 and ANSI/VITA 1.1-1997 and the VITA 41 standards cited above for VMEbus systems. For example, these standards define RP0 mechanical envelope 242, and RP2 mechanical envelope 258 on rear transition module 220. These standards further define corresponding RJ0 mechanical envelope 244, and RJ2 mechanical envelope 256 on monolithic backplane 202. Connectors in the RP0/RJ0 and RP2/RJ2 mechanical envelopes can interlock when rear transition module 220 is placed in a slot of rear portion 206 of monolithic backplane 202 of VXS multi-service platform system 200.

In an embodiment, rear transition module 220 can have an interlocking connector in the RP2 mechanical envelope 258 designed to interlock with its corresponding portion located in the RJ2 mechanical envelope 256 on the monolithic backplane 202. In an embodiment of the invention, connector in the RP2/RJ2 mechanical envelopes can be for coupling VMEbus network 108 to rear transition module 220 or for coupling corresponding payload module 214 to rear transition module 220.

When rear transition module 220 is placed in a slot and coupled to rear portion 206 of monolithic backplane 202 via connector in the P2/J2 mechanical envelope, the functionality of rear transition module 220 can be added to VXS multi-service platform system 200. This functionality can be added via directly connecting to VMEbus network 108 or by coupling to corresponding payload module 214. For example, I/O elements, and the like, on rear transition module 220 can be accessible by other payload modules in VXS multi-service platform system 200. These I/O elements can access external networks, chassis, devices, and the like, for example, external storage devices, external networks such as the Internet, other VXS computer chassis, and the like.

In another embodiment, the connector in RP0/RJ0 mechanical envelope can be for directly coupling switched fabric 110 to rear transition module 220 or for coupling corresponding payload module 214 to rear transition module 220. When rear transition module 220 is placed in a slot and coupled to rear portion 206 of monolithic backplane 202 via a connector in the RP0/RJ0 mechanical envelopes, the functionality of rear transition module 220 is added to VXS multi-service platform system 200. This functionality can be added via directly connecting to switched fabric 110 or by coupling to corresponding payload module 214. For example, I/O elements, and the like, on rear transition module 220 can be accessible by other payload modules in VXS multi-service platform system 200.

In this embodiment, rear transition module 220 can have connector 230 in the RP0 mechanical envelope 242. Rear portion 206 of monolithic backplane 202 can include corresponding connector 234 in the RJ0 mechanical envelope 244, where the connector 230 and the corresponding connector 234 are designed to interface and interlock when rear transition module 220 is inserted into VXS multi-service platform system 200. In an embodiment, connector 230 and corresponding connector 234 can be electrical, optical, radio frequency, biological, and the like, type connectors. In an embodiment, connector 230 and corresponding connector 234 are designed for use in high-speed switched fabrics and are compatible with any of a plurality of switched fabric protocols discussed above. In an example of an embodiment of the invention, connector 230 in the RP0 mechanical envelope 242 and corresponding connector 234 in the RJ0 mechanical envelope 244 can be a Tyco MultiGig RT connector manufactured by the AMP division of Tyco Electronics, Harrisburg, Pa. The invention is not limited to the use of the Tyco RT connector, and any connector capable of handling data using any of the plurality of switched fabric network standards is encompassed within the invention.

In an embodiment, switched fabric link 260 can extend switched fabric 110 from monolithic backplane 202, to rear transition module 220 through monolithic backplane 202. In an embodiment, switched fabric link 260 can communicatively couple payload module 214 to rear transition module 220. Switched fabric link 260 can extend through payload module connector 240, payload connector 238, corresponding connector 234 and connector 230. Switched fabric link 260 can include any type of medium to communicate data signals using switched fabric protocol 270, for example, copper, optical, and the like.

In an embodiment, switched fabric link 260 can originate at gateway module 261 on payload module 214. Gateway module 261 can be any combination of hardware, software, and the like that processes or creates data signals to or from switched fabric 110. In an embodiment, gateway module 261 is also coupled to switched fabric 110. Gateway module 261 can function to process incoming and outgoing data signals from VXS computer chassis 103 on switched fabric link 260 using switched fabric protocol 270.

Switched fabric link 260 can terminate at a rear transition module (RTM) bridging unit 280 on rear transition module 220. RTM bridging unit 280 can function to bridge data communicated using switched fabric protocol 270 to an external input/output (I/O) protocol 282. Data can be bridged from switched fabric link 260 using switched fabric protocol 270 to an external link 262 using external I/O protocol 282. External link 262 can extend outside of VXS computer chassis 103 from rear transition module 220 to one or more external networks, devices 263, and the like.

In an embodiment, external I/O protocol 282 transfers data at a slower rate than switched fabric protocol 270. In an embodiment, switched fabric link 260 using switched fabric protocol 270 can transfer data at a rate of at least one gigabyte per second. In an embodiment, external link 262 transfers data using external I/O protocol 282 at least an order of magnitude slower than switched fabric protocol 270. In an embodiment, external I/O protocol 282 can include any number of legacy protocols, for example and without limitation, Small Computer System Interface (SCSI), IDE, AT Attachment (ATA), RS232, PS/2, and the like.

In an embodiment, external link 262 couples front module 205 via rear transition module 220 to at least one external network, device 263, and the like. External network, device 263, and the like, can be networks or devices that operate using at least one external I/O protocol 282, for example, storage devices, keyboards, printers, and the like. Switched fabric link 260, RTM bridging unit 280 and external link 262 are configured such that switched fabric 110 is coupled to communicate with at least one external network or device 263 using switched fabric protocol 270 and external I/O protocol 282.

In the embodiment shown, only one external link 262 is shown. This is not limiting of the invention. External link 262 can be divided into any number of external links exiting VXS multi-service platform system 200. In an embodiment, external link 262 can be comprised of any number of copper links, optical links, and the like.

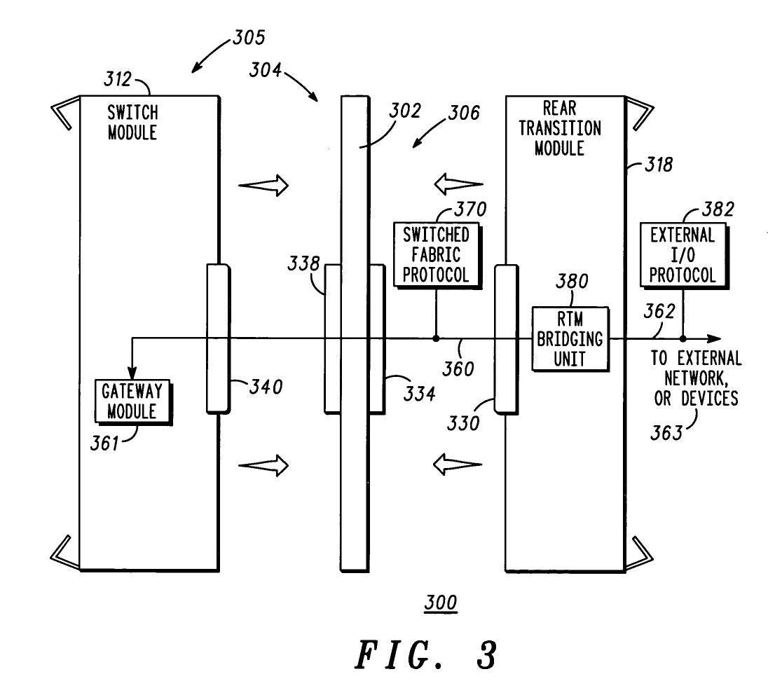

FIG. 3 depicts a VXS multi-service platform system 300 according to another embodiment of the invention. In an embodiment of the invention, monolithic backplane 302 and front module 305 have a set of interlocking connectors designed to interlock with each other when front module 305 is placed in a slot of VXS multi-service platform system 300. In the embodiment shown, front module is a switch module 312, which is coupled to interface with front portion 304 of monolithic backplane 302. Mechanical and electrical specifications for a portion of these interlocking connectors can be found in the ANSI/VITA 1-1994 and ANSI/VITA 1.1-1997 and the VITA 41 standards cited above for VMEbus systems.

Switch module 312 can have switch module connector 340 as defined in the VXS specification specified above. Monolithic backplane 302 can include backplane connector 338, where the switch module connector 340 and backplane connector 338 are designed to interface and interlock when switch module 312 is inserted into VXS multi-service platform system 300. In an embodiment, switch module connector 340 and backplane connector 338 can be electrical, optical, radio frequency, biological, and the like, type connectors. In an embodiment, switch module connector 340 and backplane connector 338 are designed for use in high-speed switched fabrics and are compatible with any of a plurality of switched fabric protocols 370 discussed above. Switched fabric 110 on monolithic backplane 302 operates using any of switched fabric protocols 370.

In an example of an embodiment of the invention, switch module connector 340 and backplane connector 338 can be a Tyco MultiGig RT connector manufactured by the AMP division of Tyco Electronics, Harrisburg, Pa. The invention is not limited to the use of the Tyco RT connector, and any connector capable of handling data using any of the plurality of switched fabric network protocols is encompassed within the invention.

In the embodiment depicted in FIG. 3, VXS multi-service platform system 300 can include rear transition module 318 coupled to interface with rear portion 306 of monolithic backplane 302. In an embodiment, rear transition module 318 is substantially coplanar with corresponding switch module 312.

In an embodiment of the invention, monolithic backplane 302 and rear transition module 318 have a set of interlocking connectors designed to interlock with each other when rear transition module 318 is placed in a slot of VXS multi-service platform system 300. Rear transition module 318 is coupled to interface with rear portion 306 of monolithic backplane 302. Mechanical and electrical specifications for a portion of these interlocking connectors can be found in the ANSI/VITA 1-1994 and ANSINITA 1.1-1997 and the VITA 41 standards cited above for VMEbus systems.

In an embodiment, rear transition module 318 can have connector 330. Rear portion 306 of monolithic backplane 302 can include corresponding connector 334, where the connector 330 and the corresponding connector 334 are designed to interface and interlock when rear transition module 318 is inserted into VXS multi-service platform system 300. In an embodiment, connector 330 and corresponding connector 334 can be electrical, optical, radio frequency, biological, and the like, type connectors. In an embodiment, connector 330 and corresponding connector 334 are designed for use in high-speed switched fabrics and are compatible with any of a plurality of switched fabric protocols discussed above. In an example of an embodiment of the invention, connector 330 and corresponding connector 334 can be a Tyco MultiGig RT connector manufactured by the AMP division of Tyco Electronics, Harrisburg, Pa. The invention is not limited to the use of the Tyco RT connector, and any connector capable of handling data using any of the plurality of switched fabric network protocols is encompassed within the invention.

In an embodiment, the connector 330 and corresponding connector 334 can be for directly coupling switched fabric 110 to rear transition module 318 or for coupling corresponding switch module 312 to rear transition module 318. When rear transition module 318 is placed in a slot and coupled to rear portion 306 of monolithic backplane 302, the functionality of rear transition module 318 is added to VXS multi-service platform system 300. This functionality can be added via directly connecting to switched fabric 110 or by coupling to corresponding switch module 312. For example, I/O elements, and the like, on rear transition module 318 can be accessible by other payload modules and/or switch module 312 in VXS multi-service platform system 300.

In an embodiment, switched fabric link 360 can extend switched fabric 110 from monolithic backplane 302, to rear transition module 318 through monolithic backplane 302. In an embodiment, switched fabric link 360 can communicatively couple switch module 312 to rear transition module 318. Switched fabric link 360 can extend through switch module connector 340, backplane connector 338, corresponding connector 334 and connector 330. Switched fabric link 360 can include any type of medium to communicate data signals using switched fabric protocol 370, for example, copper, optical, and the like.

In an embodiment, switched fabric link 360 can originate at gateway module 361 on switch module 312. Gateway module 361 can be any combination of hardware, software, and the like that processes or creates data signals to or from switched fabric 110. In an embodiment, gateway module 361 is also coupled to switched fabric 110. Gateway module 361 can function to process incoming and outgoing data signals from VXS computer chassis 103 on switched fabric link 360 using switched fabric protocol 370.

Switched fabric link 360 can terminate at a rear transition module (RTM) bridging unit 380 on rear transition module 318. RTM bridging unit 380 can function to bridge data communicated using switched fabric protocol 370 to an external input/output (I/O) protocol 382. Data can be bridged from switched fabric link 360 using switched fabric protocol 370 to an external link 362 using external I/O protocol 382. External link 362 can extend outside of VXS computer chassis 103 from rear transition module 318 to one or more external networks, devices 363, and the like.

In an embodiment, external I/O protocol 382 transfers data at a slower rate than switched fabric protocol 370. In an embodiment, switched fabric link 360 using switched fabric protocol 370 can transfer data at a rate of at least one gigabyte per second. In an embodiment, external link 362 transfers data using external I/O protocol 382 at least an order of magnitude slower than switched fabric protocol 370. In an embodiment, external I/O protocol 382 can include any number of legacy protocols, for example and without limitation, Small Computer System Interface (SCSI), IDE, AT Attachment (ATA), RS232, PS/2, and the like.

In an embodiment, external link 362 couples front module 305 via rear transition module 318 to at least one external network, device 363, and the like. External network, device 363, and the like, can be networks or devices that operate using at least one external I/O protocol 382, for example, storage devices, keyboards, printers, and the like. Switched fabric link 360, RTM bridging unit 380 and external link 362 are configured such that switched fabric 110 is coupled to communicate with at least one external network or device 363 using switched fabric protocol 370 and external I/O protocol 382.

In the embodiment shown, only one external link 362 is shown. This is not limiting of the invention. External link 362 can be divided into any number of external links exiting VXS multi-service platform system 300. In an embodiment, external link 362 can be comprised of any number of copper links, optical links, and the like.

While we have shown and described specific embodiments of the present invention, further modifications and improvements will occur to those skilled in the art. It is therefore, to be understood that appended claims are intended to cover all such modifications and changes as fall within the true spirit and scope of the invention.

1. A VXS multi-service platform system, comprising:
a VXS computer chassis;
a monolithic backplane in the VXS computer chassis;
a VMEbus network on the monolithic backplane;
a switched fabric operating coincident with the VMEbus network on the monolithic backplane;
a front module coupled to a front portion of the monolithic backplane;
a rear transition module coupled to a rear portion of the monolithic backplane, wherein the rear transition module is substantially coplanar with the front module;
a switched fabric link extending from the front module through the monolithic backplane to the rear transition module, wherein the switched fabric link operates using a switched fabric protocol; and
an RTM bridging unit on the rear transition module, wherein the switched fabric link terminates at the RTM bridging unit, and wherein the RTM bridging unit bridges the switched fabric protocol to an external link operating an external I/O protocol, wherein the external I/O protocol transfers data at least an order of magnitude slower than the switched fabric protocol, and wherein the external link extends outside of the VXS computer chassis from the rear transition module.

2. The VXS multi-service platform system of claim 1, wherein the front module is one of a payload module and a switch module.

3. The VXS multi-service platform system of claim 1, wherein the switched fabric link transfers data at least one gigabyte per second.

4. The VXS multi-service platform system of claim 1, wherein the external link couples the front module to at least one of an external network and an external device that operates using the external I/O protocol.

5. The VXS multi-service platform system of claim 1, wherein the switched fabric is coupled to communicate with at least one of an external network and an external device via the RTM bridging unit using the external I/O protocol.

6. The VXS multi-service platform system of claim 1, wherein the switched fabric link extends through a payload connector in the J0 mechanical envelope to couple a payload module to the rear transition module.

7. The VXS multi-service platform system of claim 1, wherein the switched fabric link extends through a corresponding connector in the RJ0 mechanical envelope to couple a payload module to the rear transition module.

8. The VXS multi-service platform system of claim 1, wherein the switched fabric link extends through a backplane connector to couple a switch module to the rear transition module.

9. A method, comprising:
providing a VXS computer chassis having a monolithic backplane;
operating a VMEbus network and a switched fabric coincident on the monolithic backplane;
coupling a front module on a front portion of the monolithic backplane to a rear transition module on a rear portion of the monolithic backplane via a switched fabric link, wherein the front module and the rear transition module are substantially coplanar, wherein the switched fabric link extends through the monolithic backplane, and wherein the switched fabric link operates using a switched fabric protocol; and
an RTM bridging unit coupled to the rear transition module bridging the switched fabric protocol to an external link operating an external I/O protocol, wherein the external I/O protocol transfers data at least an order of magnitude slower than the switched fabric protocol, and wherein the external link extends outside of the VXS computer chassis from the rear transition module.

10. The method of claim 9, wherein the front module is one of a payload module and a switch module.

11. The method of claim 9, wherein the switched fabric link transfers data at least one gigabyte per second.

12. The method of claim 9, further comprising coupling the front module via the external link to at least one of an external network and an external device that operates using the external I/O protocol.

13. The method of claim 9, wherein the switched fabric is coupled to communicate with at least one of an external network and an external device via the RTM bridging unit using the external I/O protocol.

14. The method of claim 9, wherein coupling the front module to the rear transition module comprises extending the switched fabric link through a payload connector in the J0 mechanical envelope.

15. The method of claim 9, wherein coupling the front module to the rear transition module comprises extending the switched fabric link through a corresponding connector in the RJ0 mechanical envelope.

16. The method of claim 9, wherein coupling the front module to the rear transition module comprises extending the switched fabric link through a backplane connector.

17. A VXS computer chassis, comprising:
a monolithic backplane;
a VMEbus network on the monolithic backplane;
a switched fabric operating coincident with the VMEbus network on the monolithic backplane;
a front module coupled to a front portion of the monolithic backplane;
a rear transition module coupled to a rear portion of the monolithic backplane, wherein the rear transition module is substantially coplanar with the front module;
a switched fabric link extending from the front module through the monolithic backplane to the rear transition module, wherein the switched fabric link operates using a switched fabric protocol; and
an RTM bridging unit on the rear transition module, wherein the switched fabric link terminates at the RTM bridging unit, and wherein the RTM bridging unit bridges the switched fabric protocol to an external link operating an external I/O protocol, wherein the external I/O protocol transfers data at least an order of magnitude slower than the switched fabric protocol, and wherein the external link extends outside of the VXS computer chassis from the rear transition module.

18. The VXS computer chassis of claim 17, wherein the front module is one of a payload module and a switch module.

19. The VXS computer chassis of claim 17, wherein the switched fabric link transfers data at least one gigabyte per second.

20. The VXS computer chassis of claim 17, wherein the external link couples the front module to at least one of an external network and an external device that operates using the external I/O protocol.

21. The VXS computer chassis of claim 17, wherein the switched fabric is coupled to communicate with at least one of an external network and an external device via the RTM bridging unit using the external I/O protocol.

22. The VXS computer chassis of claim 17, wherein the switched fabric link extends through a payload connector in the J0 mechanical envelope to couple a payload module to the rear transition module.

23. The VXS computer chassis of claim 17, wherein the switched fabric link extends through a corresponding connector in the RJ0 mechanical envelope to couple a payload module to the rear transition module.

24. The VXS computer chassis of claim 17, wherein the switched fabric link extends through a backplane connector to couple a switch module to the rear transition module.

25. A rear transition module coupled to a rear portion of a monolithic backplane of a VXS computer chassis, the rear transition module comprising:
a switched fabric link coupled to extend from a front module through the monolithic backplane, wherein the switched fabric link operates using a switched fabric protocol, wherein the switched fabric link is coupled to a switched fabric on the monolithic backplane, and wherein a VMEbus network operates coincident with the switched fabric on the monolithic backplane;
an RTM bridging unit coupled to the switched fabric link; and
an external link coupled to the RTM bridging unit, wherein the RTM bridging unit bridges the switched fabric protocol to an external I/O protocol on the external link, wherein the external I/O protocol transfers data at least an order of magnitude slower than the switched fabric protocol, and wherein the external link extends outside of the VXS computer chassis from the rear transition module.

26. The rear transition module of claim 25, wherein the front module is one of a payload module and a switch module.

27. The rear transition module of claim 25, wherein the switched fabric link transfers data at least one gigabyte per second.

28. The rear transition module of claim 25, wherein the external link couples the front module to at least one of an external network and an external device that operates using the external I/O protocol.

29. The rear transition module of claim 25, wherein the switched fabric is coupled to communicate with at least one of an external network and an external device via the RTM bridging unit using the external I/O protocol.

30. The rear transition module of claim 25, wherein the switched fabric link extends through a payload connector in the J0 mechanical envelope to couple a payload module to the rear transition module.

31. The rear transition module of claim 25, wherein the switched fabric link extends through a corresponding connector in the RJ0 mechanical envelope to couple a payload module to the rear transition module.

32. The rear transition module of claim 25, wherein the switched fabric link extends through a backplane connector to couple a switch module to the rear transition module.
